(19) United States
(12) Patent Application Publication
(10) Pub. No.: US 2010/0142133 A1
(43) Pub. Date: Jun. 10, 2010

(54) ELECTRONIC DEVICE WITH TOUCH PANEL

(76) Inventors: Wen-Chun WANG, Taichung City (TW); Chin-Chang Liu, Taichung County (TW); Kun-Chang Ho, Tai Chung City (TW); Chih-Jung Teng, Tai Chung City (TW)

Correspondence Address: Muncy, Geissler, Olds & Lowe, PLLC, 4000 Legato Road, Suite 310, FAIRFAX, VA, 22033, US

(21) Appl. No.: 12/632,990

(22) Filed: Dec. 8, 2009

(30) Foreign Application Priority Data
Dec. 9, 2008 (TW) 097222098

(51) Int. Cl. H05K 5/00

(52) U.S. Cl. 361/679.01

(57) ABSTRACT

An electronic device with touch panel has a main body, a touch panel, a case and a joint unit wherein the touch panel is pivoted on the main body and the joint unit is connected between the main body and the case. The main body has a display with an active area, and the case has a plurality of patterns. Consequently, the touch panel is capable of being positioned on the active area or the patterns of the case for the user to operate on the active area directly or patterns in the form of a keyboard.

### BACKGROUND OF THE INVENTION

1. Field of the Invention

The invention relates to an electronic device, and more particularly to an electronic device with touch panel.

2. Description of the Related Art

In order to meet touch function requirement, conventional electronic device, such as mobile phone, portable computer and so on, includes a touch panel directly mounted on the display of the electronic device such that user can operate by touching or dragging on the screen. However, the user got used of operating by keyboard might not be familiar with the above electronic device with touch panel.

With respect to the portable electronic device, the volumn, weight and operable convenience are priority concerns for the users. The portable computing device disclosed in U.S. Pat. No. 6,362,440 comprises a keyboard integrated with the substrate, a touch panel and a display whereby the user can operate through not only the touch panel but also the keyboard by pivoting the touch panel on the display. Although this kind of portable electronic device with substantial keyboard and touch panel is more user-friendly to operate, the individual components, the keyboard and the touch panel, would increase the volumn and raise the cost.

### SUMMARY OF THE INVENTION

It is therefore an apect of the present invention to provide an electronic device with touch panel capable of being positioned on a case with patterns or an active area to reduce the thickness and the material cost of the electronic device.

In accordance with the foregoing apect of the present invention, the electronic device with touch panel has a main body, a touch panel, a case and a joint unit wherein the touch panel is pivoted on the main body and the joint unit is connected between the main body and the case. The main body has a display with an active area, and the case has a plurality of patterns. Consequently, the touch panel is capable of being positioned on the active area or the patterns of the case for the user to operate on the active area directly or patterns in the form of a keyboard.

### BRIEF DESCRIPTION OF THE DRAWINGS

FIG. 1 is an exploded view of the first embodiment of the electronic device with touch panel of the present invention;

FIG. 2 is a perspective view of the first embodiment of the electronic device with touch panel shown in FIG. 1;

FIG. 3 is another perspective view of the first embodiment of the electronic device with touch panel shown in FIG. 1;

FIG. 4 is a perspective view of the second embodiment of the electronic device with touch panel of the present invention;

FIG. 5 is a perspective view of the third embodiment of the electronic device with touch panel of the present invention; and

FIG. 6 is another perspective view of the third embodiment of the electronic device with touch panel shown in FIG. 5.

### DETAILED DESCRIPTION OF THE INVENTION

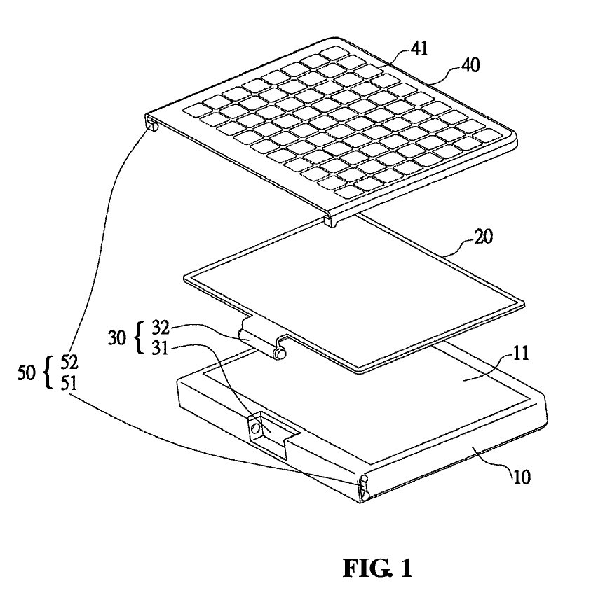

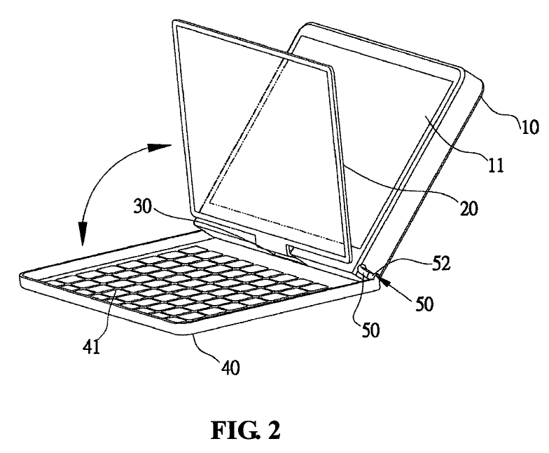

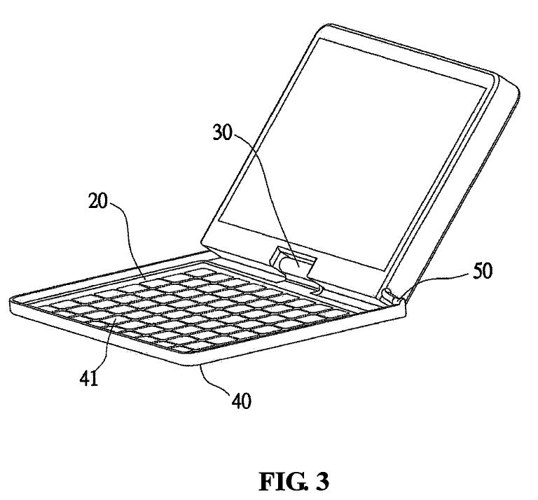

Refer to FIG. 1 to FIG. 3. FIG. 1 illustrates an exploded view of the first embodiment of the electronic device with touch panel; FIG. 2 illustrates a perspective view of the first embodiment of the electronic device with touch panel shown in FIG. 1; FIG. 3 illustrates another perspective view showing an operative condition of the first embodiment of the electronic device with touch panel.

The electronic device with touch panel of the first embodiment includes a main body 10, a touch panel 20, a pivot unit 30, a case 40 and a joint unit 50. The main body 10, such as mobile phone, portable computer, global position system and the like, has a display to provide an active area 11 wherein the display could be liquid crystal display (LCD), organic light emitting diode (OLED) or electrophoretic display (EPD).

The transparent touch panel 20 is pivoted on the main body 10 to face the active area 11, and has a single sensing surface or double sensing surfaces which is shown in the first embodiment.

The pivot unit 30 has a slot 31 and a pin 32 being received within the slot 31. The slot 31 is defined on the main body 10, and the pin 32 is disposed on the touch panel 20 such that the touch panel 20 is capable of being rotated around the main body 10.

The case 40 has a plurality of keyboard-like patterns 41 facing the active area 11 wherein the patterns are defined by a bistable display, such as electrophoretic display (EPD), electrowetting display (EWD) or cholesteric liquid crystal display (CHLCD), disposed thereon.

The joint unit 50 is connected between the main body 10 and the case 40, and has a pair of first rails 51 and a pair of protrusions 52 retractably received within the first rails 51. The first rails 51 are respectively defined on two end surfaces of the main body 10, and the protrusions 52 are defined on opposite flanks of the case 40.

With regard to operable structure illustrated in FIG. 2, the case 40 is located away from the main body 10 via the joint unit 50, and the touch panel 20 is pivoted around to be positioned on the active area 11 of the main body 10 whereby the user can directly touch or drag on the active area 11 to input the information.

In the other operable structure illustrated in FIG. 3, the case 40 is also located away from the main body 10 via the joint unit 50, and the transparent touch panel 20 is pivoted around to be positioned on the case 40 thereby showing the patterns 41. Meanwhile, the touch panel 20 is modified to another operation mode defining multiple blocks corresponding to the keyboard-like patterns 41 such that the blocks respectively have their own functions equivalent to the corresponding patterns 41 in the form of the keyboard. Therefore, the user can control the electronic device in a traditional operation enviroment through the integration between the case 40 with keyboard-like patterns 41 and the touch panel 20.

With the touch panel 20 capable of being modified to different kinds of the operation mode and pivoted around to positioned on the case 40 or on the active area 11, the user can operate selectively without extra substantial keyboard. Thus, the thickness and the weight are reduced to save the material cost and meet the enviromental protection requirement. In addition, a first universal joint (not shown) can be substituted for the pivot unit 30 connect between the main body 10 and the touch panel 20 to reach the abovementioned operation wherein the first universal joint is conventional techknowledge such that there is no more detailed description herein.

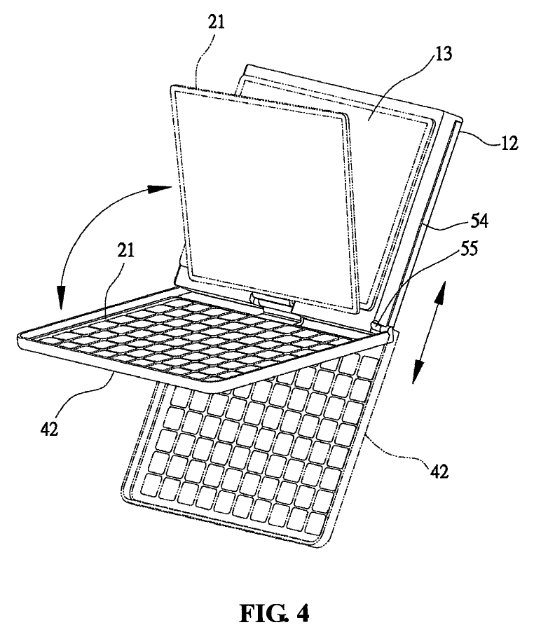

Refer to FIG. 4 which illustrates a second embodiment of the electronic device with touch panel of the present invention. In the second embodiment, the joint unit 50 has a pair of second rails 54 respectively defined on opposite flanks of the main body 12 such that the protrusions 55 is received movably within the second rails 54 and rotated around the main body 12 from one end thereof. Compared with the first embodiment, the case 42 can be kept within the main body 12 through the protrusions 55 and the second rails 54 when the touch panel 21 is positioned on the active area 13 for the user to operate directly.

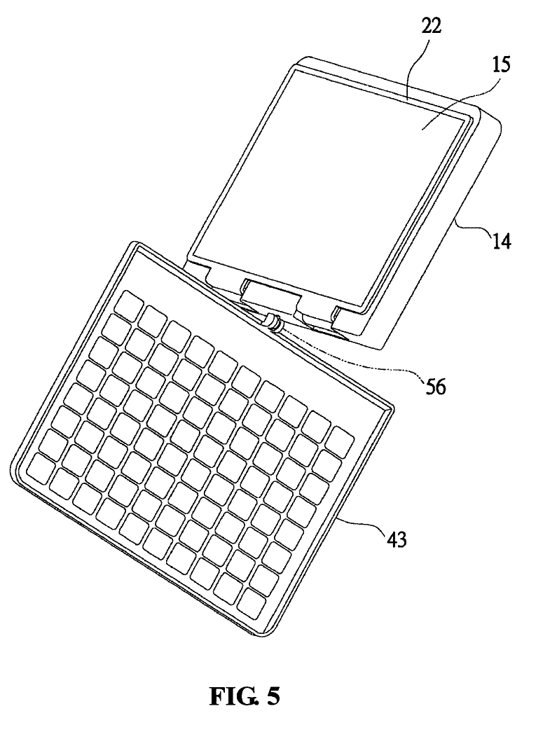

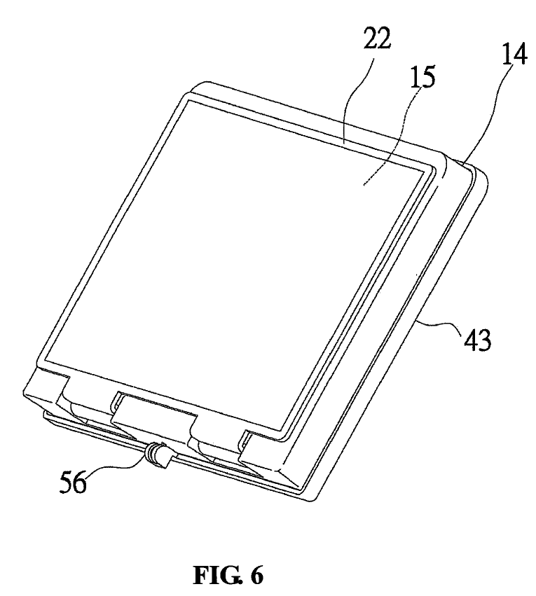

Refer to FIG. 5 and FIG. 6. FIG. 5 illustrates a third embodiment of the electronic device with touch panel of the present invention; FIG. 6 illustrates the storage condition of the third embodiment shown in FIG. 5. In the third embodiment, the joint unit 56 is a second universal joint connected between the case 43 and the main body 14 whereby the case 43 can be located behind the main body 14 (shown in FIG. 6) or in front of the main body 14 as a cover of the touch panel 22 (not shown). After the case 43 is pivoted from the second universal joint and rotated through 180 degrees to show the keyboard-like patterns on which the touch panel 22 is positioned, the user can regulate the angel between the case 43 and the main body 14 to provide a suitable working condition. In other working condition shown in FIG. 6, the touch panel 22 is positioned on the active area 15 of the main body 14 for the user to operate directly.

Although the present invention has been described in considerable detail with reference to certain preferred embodiments thereof, other embodiments are possible. Therefore, their spirit and scope of the appended claims should no be limited to the description of the preferred embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device with touch panel, comprising:
a main body comprising a display with an active area;
a touch panel pivoted on the main body;
a case comprising a plurality of patterns; and
a joint unit connected between the main body and the case;
whereby, the touch panel is capable of being positioned on the active area or the patterns of the case.

2. The electronic device with touch panel of claim 1, further comprising a pivot unit of a slot and a pin received within the slot, wherein the slot is defined on the main body and the pin is disposed on the touch panel which is capable of being rotated around the main body.

3. The electronic device with touch panel of claim 1, further comprising a first universal joint connected between the main body and the touch panel.

4. The electronic device with touch panel of claim 1, wherein the touch panel is a capacitive touch panel with double sensing surfaces.

5. The electronic device with touch panel of claim 4, further comprising a pivot unit of a slot and a pin received within the slot, wherein the slot is defined on the main body and the pin is disposed on the touch panel which is capable of being rotated around the main body.

6. The electronic device with touch panel of claim 4, further comprising a first universal joint connected between the main body and the touch panel.

7. The electronic device with touch panel of claim 1, further comprising a first universal joint connected between the main body and the touch panel, and wherein the touch panel is a capacitive touch panel with single sensing surface.

8. The electronic device with touch panel of claim 1, wherein the patterns are keyboard-like patterns.

9. The electronic device with touch panel of claim 1, wherein the joint unit comprises a pair of first rails and a pair of protrusions retractably received within the first rails wherein the first rails are respectively defined on two end surfaces of the main body, and the protrusions are defined on opposite flanks of the case.

10. The electronic device with touch panel of claim 9, wherein the joint unit comprises a pair of second rails respectively defined on opposite flanks of the main body.

11. The electronic device with touch panel of claim 1, wherein the joint unit is a second universal joint connected between the main body and the case.

12. The electronic device with touch panel of claim 1, wherein the case comprises a bistable display disposed thereon to define the patterns.

13. The electronic device with touch panel of claim 12, wherein the bistable display is electrophoretic display (EPD), electrowetting display (EWD) or cholesteric liquid crystal display (CHLCD).
